(19) United States
(12) Patent Application Publication
(10) Pub. No.: US 2024/0186114 A1
(43) Pub. Date: Jun. 6, 2024

(54) PLASMA PROCESSING APPARATUS AND ASSEMBLY METHOD OF RESONATOR ARRAY STRUCTURE

(71) Applicant: TOKYO ELECTRON LIMITED, Tokyo (JP)

(72) Inventors: Kazushi KANEKO, Yamanashi (JP); Satoru Kawakami, Yamanashi (JP); Hiroshi Kondo, Tjokyo (JP); Eiki Kamata, Yamanashi (JP); Shin Oowada, Tokyo (JP)

(21) Appl. No.: 18/515,120

(22) Filed: Nov. 20, 2023

(30) Foreign Application Priority Data
Dec. 1, 2022 (JP) 2022-192567

(51) Int. Cl. H01J 37/32

(52) U.S. Cl. CPC H01J 37/32247; H01J 37/3222; H01J 37/32449

(57) ABSTRACT

Provided is a plasma processing apparatus comprising a processing container configured to provide a processing space; an electromagnetic wave generator configured to generate electromagnetic waves for plasma excitation supplied to the processing space; a dielectric provided with a first surface thereof facing the processing space; an electromagnetic wave supply portion configured to supply the electromagnetic waves to the processing space through the dielectric; and a resonator array structure located along the first surface of the dielectric within the processing container, wherein the resonator array structure includes a base plate having a groove on a surface on the processing space side; a plurality of resonators capable of resonating with a magnetic field component of the electromagnetic wave and having a size smaller than a wavelength of the electromagnetic wave; and a pressing member configured to press the plurality of resonators.

### CROSS-REFERENCE TO RELATED APPLICATIONS

This application claims priority to Japanese Patent Application No. 2022-192567, filed on Dec. 1, 2022, the entire contents of which are incorporated herein by reference.

### TECHNICAL FIELD

The present disclosure relates to a plasma processing apparatus and an assembly method for a resonator array structure.

### BACKGROUND

Japanese Laid-open Patent Publication No. 2009-245593 discloses a plasma processing apparatus that supplies microwaves for plasma excitation to a processing container to generate plasma.

### SUMMARY

The present disclosure provides a plasma processing apparatus and an assembly method for a resonator array structure that can realize high density in a wide range of plasma.

In accordance with an aspect of the present disclosure, there is provided a plasma processing apparatus comprising a processing container configured to provide a processing space; an electromagnetic wave generator configured to generate electromagnetic waves for plasma excitation supplied to the processing space; a dielectric provided with a first surface thereof facing the processing space; an electromagnetic wave supply portion configured to supply the electromagnetic waves to the processing space through the dielectric; and a resonator array structure located along the first surface of the dielectric within the processing container, wherein the resonator array structure includes a base plate having a groove on a surface on the processing space side; a plurality of resonators capable of resonating with a magnetic field component of the electromagnetic wave and having a size smaller than a wavelength of the electromagnetic wave; and a pressing member configured to press the plurality of resonators, wherein the plurality of resonators includes a dielectric plate; and a conductor member being stacked on one side of the dielectric plate, wherein a first side of each of the plurality of resonators are fitted into the groove, and wherein the pressing member presses the plurality of resonators toward the base plate.

### BRIEF DESCRIPTION OF THE DRAWINGS

FIG. 1 is a schematic cross-sectional view illustrating an example of a configuration of a plasma processing apparatus according to a first embodiment.

FIG. 2 is a plan view illustrating an example of a configuration of a dielectric window and a resonator array structure according to the first embodiment as viewed from below.

FIG. 3 is a diagram illustrating an example of a configuration of a card-shaped resonator according to the first embodiment.

FIG. 4 is a diagram illustrating an example of a configuration of a card-shaped resonator according to the first embodiment.

FIG. 5 is a diagram illustrating another example of the configuration of the card-shaped resonator according to the first embodiment.

FIG. 6 is a diagram illustrating an example of a cross section of the card-shaped resonator according to the first embodiment.

FIG. 7 is a diagram illustrating an example of a relationship between an S21 value of the card-shaped resonator and a frequency of microwave.

FIG. 8 is a diagram illustrating an example of assembly of the resonator array structure according to the first embodiment.

FIG. 9 is a side view illustrating an example taken along an arrow A in FIG. 8.

FIG. 10 is a top view illustrating an example taken along an arrow B in FIG. 8.

FIG. 11 is a diagram illustrating an example of assembly of the resonator array structure according to the first embodiment.

FIG. 12 is a side view illustrating an example taken along an arrow C in FIG. 11.

FIG. 13 is a cross-sectional view illustrating an example of a XIII-XIII cross section of FIG. 11.

FIG. 14 is a perspective view illustrating an example of a resonator array structure according to Modification Example 1.

FIG. 15 is a diagram illustrating an example of a range of shaking within a groove of the card-shaped resonator.

FIG. 16 is a cross-sectional view illustrating an example of a card-shaped resonator and a base plate according to Modification Example 2.

FIG. 17 is a flowchart illustrating an example of an assembly method for a resonator array structure according to the first embodiment.

FIG. 18 is a diagram illustrating an example of an array of card-shaped resonators according to Modification Example 3.

FIGS. 19A and 19B are diagrams illustrating an example of an array of card-shaped resonators according to Modification Example 4.

FIG. 20 is a diagram illustrating an example of an array of card-shaped resonators according to Modification Example 5.

FIG. 21 is a diagram illustrating an example of an array of card-shaped resonators according to Modification Example 6.

FIG. 22 is a diagram illustrating an example of an array of card-shaped resonators according to Modification Example 7.

FIGS. 23A and 23B are diagrams illustrating an example of an array of card-shaped resonators according to Modification Example 8.

FIG. 24 is a diagram illustrating an example of an array of card-shaped resonators according to Modification Example 9.

FIGS. 25A and 25B are diagrams illustrating an example of an array of card-shaped resonators according to Modification Example 10.

FIG. 26 is a diagram illustrating an example of assembly of a resonator array structure according to a second embodiment.

FIG. 27 is a diagram illustrating an example of a configuration of the rectangular-shaped resonator according to the second embodiment.

FIG. 28 is a diagram illustrating an example of a configuration of the rectangular-shaped resonator according to the second embodiment.

FIG. 29 is a diagram illustrating an example of a configuration of the rectangular-shaped resonator according to the second embodiment.

### DETAILED DESCRIPTION

Hereinafter, embodiments of the disclosed plasma processing apparatus and assembly method for a resonator array structure will be described in detail on the basis of the drawings. Further, the disclosed technology is not limited to the following embodiments.

However, in a plasma processing using microwaves for plasma excitation, power of microwaves supplied into a processing container may be increased in order to increase an electron density of plasma. As the power of the microwaves supplied into the processing container is increased, the electron density of the plasma can be increased.

Here, it is known that, when the electron density of the plasma reaches a specific upper limit due to an increase in the power of the microwaves supplied into the processing container, a permittivity of a space within the processing container becomes negative. This upper limit of the electron density is appropriately called a “cutoff density.” Further, a refractive index is known as an index indicating whether microwaves propagate through a space. The refractive index N is expressed by Equation (1) below.

N=√ε√μ (1)

Here, ε: permittivity, and μ: permeability

The permeability is generally positive, and thus, when the permittivity of the space within the processing container becomes negative, the refractive index of the space within the processing container becomes a pure imaginary number according to Equation (1) above. Accordingly, the microwaves are attenuated and cannot propagate through the space within the processing container. Thus, when the electron density of the plasma reaches the cutoff density, the microwaves cannot propagate in the space within the processing container, and thus, the power of the microwaves is not sufficiently absorbed by the plasma. As a result, there is a problem that an increase in density of the plasma generated in the processing container in a wide range is hindered.

Therefore, a technology capable of realizing high density in a wide range of plasma is expected.

### First Embodiment

### [Configuration of Plasma Processing Apparatus]

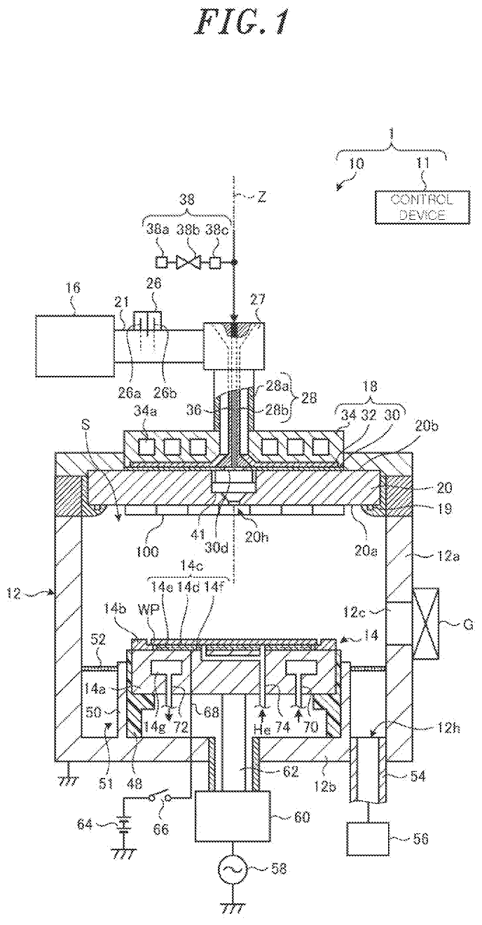

FIG. 1 is a schematic cross-sectional view illustrating an example of a configuration of a plasma processing apparatus 1 according to a first embodiment. The plasma processing apparatus 1 includes an apparatus body 10 and a control device 11. The apparatus body 10 includes a processing container 12, a stage 14, a microwave output apparatus (an example of an electromagnetic wave generator) 16, an antenna 18, a dielectric window 20, and a resonator array structure 100.

The processing container 12 is formed in a substantially cylindrical shape, for example, by using aluminum of which a surface has been anodized, and provides a substantially cylindrical processing space S therein. The processing container 12 is securely grounded. Further, the processing container 12 includes a side wall 12a and a bottom 12b. A central axis of the side wall 12a is defined as an axis Z. The bottom 12b is provided on the lower end side of the side wall 12a. An exhaust port 12h for exhaust is provided at the bottom 12b. Further, an upper end portion of the side wall 12a is open. Further, an inner wall surface of the side wall 12a faces the processing space S. That is, the side wall 12a is provided with an inner wall surface thereof facing the processing space S.

An opening 12c for loading/unloading an object to be processed WP in the side wall 12a. The opening 12c is opened and closed by a gate valve G.

The dielectric window 20 is provided at the upper end portion of the side wall 12a, and blocks an opening of the upper end portion of the side wall 12a from above. A lower surface (an example of a first surface) 20a of the dielectric window (an example of a dielectric) 20 faces the processing space S. That is, the dielectric window 20 is provided with a lower surface 20a thereof facing the processing space S. An O-ring 19 is disposed between the dielectric window 20 and an upper end portion of the side wall 12a.

The stage 14 is accommodated within the processing container 12. The stage 14 is provided to face the dielectric window 20 in a direction of the axis Z. A space between the stage 14 and the dielectric window 20 is a processing space S. The object to be processed WP is mounted on the stage 14.

The stage 14 includes a base 14a and an electrostatic chuck 14c. The base 14a is formed of a conductive material such as aluminum in a substantially disk shape. The base 14a is disposed within the processing container 12 so that a central axis of the base 14a approximately matches the axis Z.

The base 14a is supported by a cylindrical support portion 48 formed of an insulating material and extending in the axis Z direction. A conductive cylindrical support portion 50 is provided on an outer circumference of the cylindrical support portion 48. The cylindrical support portion 50 extend from the bottom 12b of the processing container 12 toward the dielectric window 20 along the outer circumference of the cylindrical support portion 48. A ring-shaped exhaust passage 51 is formed between the cylindrical support portion 50 and the side wall 12a.

A ring-shaped baffle plate 52 with a plurality of through holes formed in a thickness direction is provided in an upper portion of the exhaust passage 51. The above-described exhaust port 12h is provided under the baffle plate 52. An exhaust apparatus 56 including a vacuum pump such as a turbomolecular pump, an automatic pressure control valve, or the like is connected to the exhaust port 12h through an exhaust pipe 54. Using the exhaust apparatus 56, the processing space S can be depressed to a desired vacuum level.

The base 14a functions as a high frequency electrode. A high frequency power supply 58 for RF bias is electrically connected to the base 14a via a power supply rod 62 and a matching unit 60. The high frequency power supply 58 supplies a bias power at a predetermined frequency (for example, 13.56 MHz) suitable for control of energy of ions attracted to the object to be processed WP through the matching unit 60 and the power supply rod 62 to the base 14a.

The matching unit 60 accommodates a matcher for matching between an impedance on the high frequency power supply 58 side and an impedance on the load side, mainly the electrodes, the plasma, and the processing container 12. The matcher includes a blocking capacitor for generating a self-bias.

The electrostatic chuck 14c is provided on an upper surface of the base 14a. The electrostatic chuck 14c attracts and holds the object to be processed WP using an electrostatic force. The electrostatic chuck 14c has a substantially disk-shaped outward form and includes an electrode 14d, an insulating film (dielectric film) 14e, and an insulating film (dielectric film) 14f. The electrostatic chuck 14c is disposed on the upper surface of the base 14a so that a central axis of the electrostatic chuck 14c approximately matches the axis Z. The electrode 14d of the electrostatic chuck 14c is formed of a conductive film and is provided between the insulating film 14e and the insulating film 14f. A direct current power supply 64 is electrically connected to the electrode 14d via a coated wire 68 and a switch 66. The electrostatic chuck 14c can adsorb and hold the object to be thereof using processed WP on upper an surface an electrostatic force generated by a direct current voltage applied from the direct current power supply 64. The upper surface of the electrostatic chuck 14c is a mounting surface on which the object to be processed WP is mounted, and faces the processing space S. That is, the electrostatic chuck 14c is provided so that the upper surface which is the mounting surface faces the processing space S. Further, an edge ring 14b is provided on the base 14a. The edge ring 14b is disposed to surround the object to be processed WP and the electrostatic chuck 14c. The edge ring 14b is sometimes called a focus ring.

A flow path 14g is provided inside the base 14a. A refrigerant is supplied to the flow path 14g through a pipe 70 from a chiller unit (not illustrated). The refrigerant supplied to the flow path 14g returns to the chiller unit through the pipe 72. The refrigerant of which a temperature is controlled by the chiller unit circulates the inside of the flow path 14g of the base 14a, so that a temperature of the base 14a is controlled. When the temperature of the base 14a is controlled, a temperature of the object to be processed WP on the electrostatic chuck 14c is controlled via the electrostatic chuck 14c on the base 14a.

Further, a pipe 74 for supplying a heat transfer gas such as a He gas to between the upper surface of the electrostatic chuck 14c and a back surface of the object to be processed WP is formed on the stage 14.

A microwave output apparatus 16 outputs microwaves (an example of electromagnetic waves) for exciting a processing gas supplied into the processing container 12. In the microwave output apparatus 16, adjustment of a frequency, power, and bandwidth of the microwaves is possible. The microwave output apparatus 16 can generate microwaves at a single frequency, for example, by setting the bandwidth of the microwaves to approximately 0. Further, the microwave output apparatus 16 can generate microwaves containing a plurality of frequency components belonging to a predetermined frequency bandwidth (hereinafter appropriately referred to as “broadband microwaves”). A power of the plurality of frequency components may be the same, or only s center frequency component within the band may have a power higher than those of the other frequency components. The microwave output apparatus 16 may adjust the power of the microwave, for example, within a range of 0 W to 5000 W. The microwave output apparatus 16 may adjust a frequency of the microwaves or a central frequency of the broadband microwave within a range of, for example, 2.3 GHZ to 2.5 GHZ, and may adjust the bandwidth of the broadband microwave within the range of, for example, 0 MHz to 100 MHZ. Further, the microwave output apparatus 16 may adjust a frequency pitch (carrier pitch) of the plurality of frequency components of the broadband microwave within a range of, for example, 0 to 25 KHz.

Further, the apparatus body 10 includes a waveguide 21, a tuner 26, a mode converter 27, and a coaxial waveguide 28. An output portion of the microwave output apparatus 16 is connected to one end of the waveguide 21. The other end of the waveguide 21 is connected to the mode converter 27. The waveguide 21 is, for example, a rectangular waveguide. The tuner 26 is provided in the waveguide 21. The tuner 26 includes a movable plate 26a and a movable plate 26b. An amount of protrusion of each of the movable plates 26a and 26b with respect to an internal space of the waveguide 21 is adjusted so that impedance of the microwave output apparatus 16 can be matched with impedance of a load.

The mode converter 27 converts the mode of the microwaves output from the waveguide 21 and supplies the microwaves of which the mode has been converted, to the coaxial waveguide 28. The coaxial waveguide 28 includes an outer conductor 28a and an inner conductor 28b. The outer conductor 28a and the inner conductor 28b have a substantially cylindrical shape. The outer conductor 28a and the inner conductor 28b are disposed on an upper portion of the antenna 18 so that central axes of the outer conductor 28a and the inner conductor 28b approximately match the axis Z. The coaxial waveguide 28 transmits the microwaves of which the mode has been converted by the mode converter 27 to the antenna 18.

The antenna 18 supplies microwaves to the processing space S. The antenna 18 is an example of an electromagnetic wave supply portion. The antenna 18 is provided on an upper surface 20b of the dielectric window 20 and supplies the microwaves to the processing space S through the dielectric window 20. The antenna 18 includes a slot plate 30, a dielectric plate 32, and a cooling jacket 34. The slot plate 30 is made of conductive metal in a substantially disk shape. The slot plate 30 is provided on the upper surface 20b of the dielectric window 20 so that a central axis of the slot plate 30 matches the axis Z. A plurality of slot holes are formed in the slot plate 30. The plurality of slot holes constitute, for example, a plurality of slot pairs. Each of the plurality of slot pairs includes two slot holes having a shape of a long hole, which extend in directions intersecting each other. The plurality of slot pairs are arranged along one or more concentric circles around the central axis of the slot plate 30. Further, a through hole 30d through which a conduit 36 to be described below can pass is formed in a central portion of the slot plate 30.

The dielectric plate 32 is formed of a dielectric material such as quartz in a substantially disk shape. The dielectric plate 32 is provided on the slot plate 30 so that central axis of the dielectric plate 32 approximately matches the axis Z. The cooling jacket 34 is provided on the dielectric plate 32. The dielectric plate 32 is provided between the cooling jacket 34 and the slot plate 30.

A surface of the cooling jacket 34 is conductive. A flow path 34a is formed inside the cooling jacket 34. A refrigerant is supplied to the flow path 34a from the chiller unit (not illustrated). A lower end of the outer conductor 28a is electrically connected to an upper surface of the cooling jacket 34. Further, end of the inner conductor 28b passes through openings formed in central portions of the cooling jacket 34 and the dielectric plate 32 and is electrically connected to the slot plate 30.

The microwaves propagating within the coaxial waveguide 28 propagate within the dielectric plate 32 and are radiated into the processing space S from the plurality of slot holes of the slot plate 30 through the dielectric window 20.

The resonator array structure 100 is formed by arranging a plurality of resonators that are capable of resonating with the magnetic field component of the microwaves and have a size smaller than the wavelength of the microwave, and is located within the processing container 12.

The resonator array structure 100 is located within the processing container 12, so that the microwaves supplied to the processing space S by the antenna 18 can resonate with the plurality of resonators of the resonator array structure 100. The resonance between the microwaves and the plurality of resonators allows the microwave to be efficiently supplied to the processing space S of the processing container 12, and allows the permeability of the processing space S to be made negative. When the permeability of the processing space S is negative, the electron density of the plasma generated within the processing space S reaches the cutoff density, and even when the permittivity of the processing space S is negative, the refractive index becomes a real number according to Equation (1) above, and thus, the microwaves can propagate in the processing space S. Accordingly, even when the electron density of the plasma generated within the processing space S reaches the cutoff density, microwaves can propagate beyond a skin depth of the plasma, and the power of the microwaves is efficiently absorbed by the plasma. As a result, it is possible to generate high density plasma in a wide range beyond the skin depth of the plasma. That is, with the plasma processing apparatus 1 according to the present embodiment, it is possible to realize high density in a wide range of plasma by the resonator array structure 100 being located in the processing container 12.

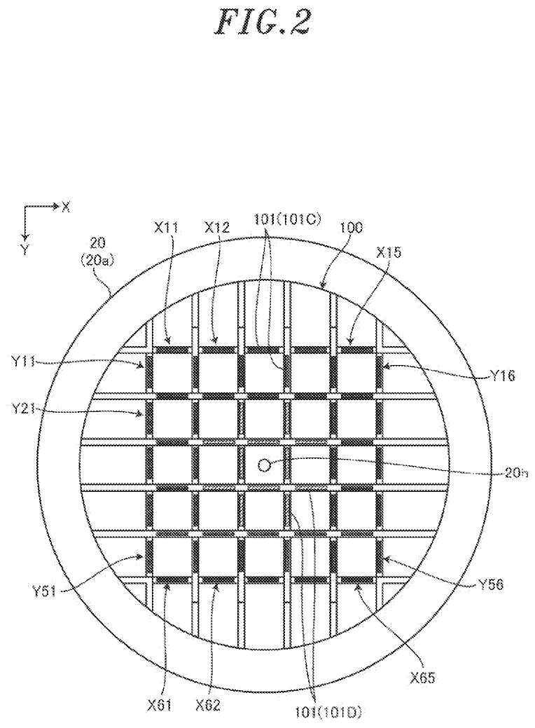

Here, a detailed configuration of the resonator array structure 100 will be described with reference to FIGS. 1 and 2. FIG. 2 is a plan view illustrating an example of a configuration of the dielectric window 20 and the resonator array structure 100 according to the first embodiment as viewed from below. In FIG. 2, the lower surface 20a of the dielectric window 20 is illustrated in a disk shape.

As illustrated in FIGS. 1 and 2, the resonator array structure 100 is disposed along the lower surface 20a of the dielectric window 20.

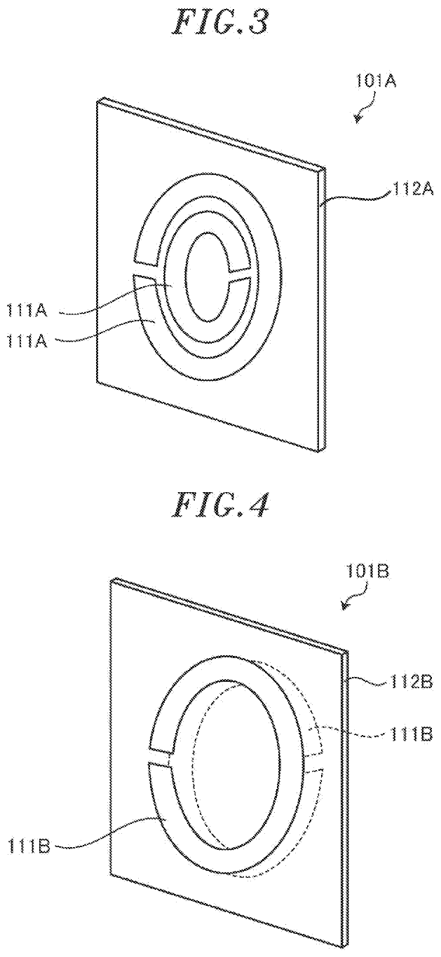

The resonator array structure 100 is formed by arranging the plurality of resonators that are capable of resonating with the magnetic field component of the microwaves and have a size smaller than the wavelength of the microwave in a lattice shape. Specifically, the plurality of resonators 101 include at least one of the resonators 101A and 101B illustrated in FIGS. 3 and 4. Each of the plurality of resonators 101 constitutes a series resonance circuit configured of a capacitor equivalent element and a coil equivalent element. The series resonance circuit is realized by patterning a conductor on a plane.

FIG. 3 is a diagram illustrating an example of a configuration of a card-shaped resonator 101A according to the first embodiment. The card-shaped resonator 101A illustrated in FIG. 3 has a structure in which two C-shaped ring members 111A made of a conductor, oriented in opposite directions, and having a concentric shape are stacked on one side of a dielectric plate 112A. A condenser equivalent element is formed on facing surfaces of the inner ring member 111A and the outer ring member 111A or at both end portions of each ring member 111A, and a coil equivalent element is formed along each ring member 111A. This allows the resonator 101A to constitute a series resonance circuit.

FIG. 4 is a diagram illustrating an example of a configuration of the card-shaped resonator 101B according to the first embodiment. The card-shaped resonator 101B illustrated in FIG. 4 has a structure in which a dielectric plate 112B is disposed between two C-shaped ring members 111B made of a conductor, which are the ring members 111B disposed adjacent to each other in opposite directions. That is, In the resonator 101B, the dielectric plate 112B is fitted between the two C-shaped ring members 111B in opposite directions. A condenser equivalent element is formed on facing surfaces of the two C-shaped ring members 111B or at both end portions of each ring member 111B, and a coil equivalent element is formed along each ring member 111B. This allows the resonator 101B to constitute a series resonance circuit. Further, the card-shaped resonator 101B can also be expressed as being formed in a card shape for each set of two C-shaped ring members 111B.

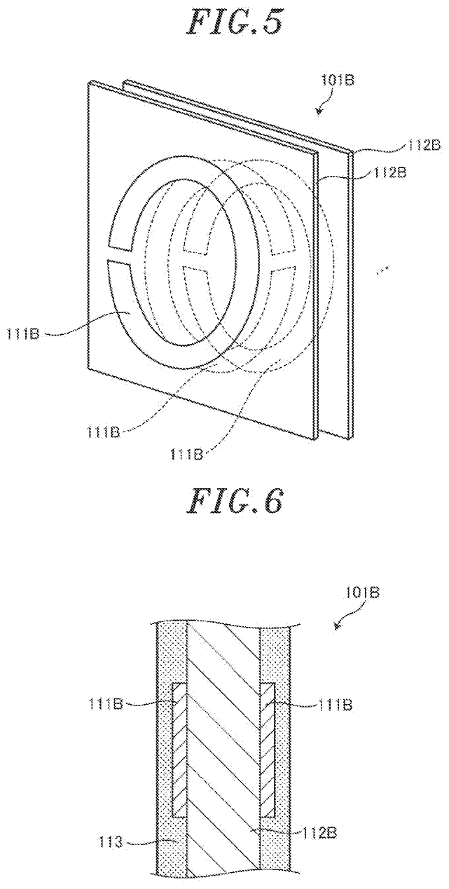

Further, in the resonator 101B illustrated in FIG. 4, the number of dispositions of ring members 111B (hereinafter also appropriately referred to as “number of stacks”) is 2, but the number of stacks of ring members 111B may be greater than 2. FIG. 5 is a diagram illustrating another example of the configuration of the card-shaped resonator 101B according to the first embodiment. The resonator 101B illustrated in FIG. 5 has a structure in which the dielectric plate 112B is disposed between of N (N≥2) C-shaped ring members 111B made of a conductor, which are the ring members 111B disposed adjacent to each other in opposite directions. With this structure, the resonator 101B can also constitute a series resonance circuit.

Further, an insulating film may be formed on each of the plurality of resonators 101. FIG. 6 is a diagram illustrating an example of a cross section of the card-shaped resonator 101B according to the first embodiment. In FIG. 6, a side cross section of the resonator 101B illustrated in FIG. 4 is illustrated. An insulating film (an example of a dielectric film) 113 is formed on a surface of the resonator 101B. A material of the film 113 is, for example, ceramic. The thickness of the film 113 is, for example, in a range of 0.001 mm to 2 mm. The insulating film 113 is formed on each of the plurality of resonators 101, thereby curbing abnormal discharge in each of the plurality of resonators 101.

FIG. 1 is referred to again. The conduit 36 is provided on the inner side of the inner conductor 28b of the coaxial waveguide 28. The through hole 30d through which the conduit 36 can pass is formed in the central portion of the slot plate 30. The conduit 36 extend portions through the inside of the inner conductor 28b and is connected to the gas supply portion 38.

The gas supply portion 38 supplies a processing gas for processing the object to be processed WP to the conduit 36. The gas supply portion 38 includes a gas supply source 38a, a valve 38b, and a flow rate controller 38c. The gas supply source 38a is a supply source for the processing gas. The valve 38b controls supplying and supply stopping of the processing gas from the gas supply source 38a. The flow rate controller 38c is, for example, a mass flow controller, and controls a flow rate of the process gas from the gas supply source 38a.

Further, the apparatus body 10 includes an injector 41. The injector 41 supplies a gas from the conduit 36 to a through hole 20h formed in the dielectric window 20. The gas supplied to the through hole 20h of the dielectric window 20 is injected into the processing space S, and is excited by the microwaves supplied to the processing space S from the antenna 18 through the dielectric window 20. Accordingly, the processing gas is converted into plasma within the processing space S, and the object to be processed WP is processed by ions and radicals contained in the plasma.

The control device 11 includes a processor, a memory, and an input and output interface. A program, process recipe, and the like are stored in the memory. The processor centrally controls each portion of the apparatus body 10 through the input and output interface on the basis of the process recipe stored in the memory by reading and executing the program from the memory.

For example, when plasma is generated in the processing space S, the control device 11 performs control so that the microwaves supplied to the processing space S by the antenna 18 resonate with the plurality of resonators 101, in a target frequency band higher than a resonance frequency of the plurality of resonators 101. Here, the resonance frequency is, for example, a frequency at which a transmission characteristic value (for example, a S21 value) of the plurality of resonators 101 becomes a minimum value.

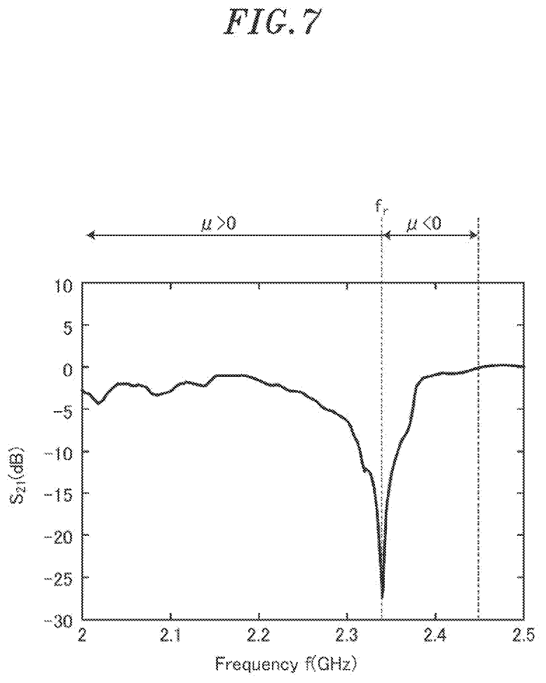

FIG. 7 is a diagram illustrating an example of a relationship between the S21 value of the card-shaped resonator and a frequency of the microwave. When a frequency of the microwave supplied to the processing space S by the antenna 18 matches the resonance frequency fr (=about 2.35 GHz) of the plurality of resonators 101, the S21 value of the plurality of resonators 101 becomes a minimum value, and resonance between the microwave and the plurality of resonators 101 occurs. The resonance between the microwave and the plurality of resonators 101 is maintained even in a predetermined frequency band (for example, about 0.1 GHZ) higher than the resonance frequency fr of the plurality of resonators 101. In the predetermined frequency band higher than the resonance frequency fr of the plurality of resonators 101, both the permittivity and the permeability of the processing space S can be made negative due to the resonance of the microwave and the plurality of resonators 101, and it is possible to propagate microwaves in the processing space S, as viewed from Equation (1) above. The target frequency band in the present embodiment is set to a predetermined frequency band (for example, about 0.1 GHZ) higher than the resonance frequency fr of the plurality of resonators 101. The target frequency band is preferably within 0.05 times the resonance frequency fr of the plurality of resonators 101, for example. Further, in measurement of the resonance frequency fr of the card-shaped resonator 101, for example, the resonance frequency fr can be measured using a vector network analyzer in which transmitting and receiving antennas are disposed in a direction parallel to the ring member 111B of the card-shaped resonator 101B.

Further, for propagation of electromagnetic waves for a plurality of resonators, a relationship between a resonance frequency and a refractive index, permittivity, and permeability is reported, for example, by D. R. Smith, D. C. Vier, Th. Koschny, and C. M. Soukoulis in “Electromagnetic parameter retrieval from inhomogeneous meta materials” in “PHYSICAL REVIEW E 71, 036617 (2005)”.

Thus, even when the electron density of the plasma reaches the cutoff density due to resonance between the microwaves and the plurality of resonators 101 in the target frequency band higher than the resonance frequency fr of the plurality of resonators 101, the propagation of the microwave can be made beyond the skin depth of the plasma. To this end, power of microwaves can be efficiently absorbed into the plasma. As a result, it is possible to generate high density plasma in a wide range beyond the skin depth of the plasma. That is, with the plasma processing apparatus 1 according to the present embodiment, it is possible to realize high density in a wide range of plasma through resonance between the microwaves and the plurality of resonators 101 in the target frequency band higher than the resonance frequency fr of the plurality of resonators 101.

[Details of Resonator Array Structure]

Next, details of the resonator array structure 100 will be described. As illustrated in FIG. 2, the resonator array structure 100 includes card-shaped resonators 101 disposed in a lattice shape. Further, in the following description, the resonator array structure 100 may be referred to as a meta material 100, and the card-shaped resonator 101 may be referred to as a meta atom 101. In the example of FIG. 2, the meta atoms 101 are disposed so that five columns of cells surrounded by the meta atoms 101 are formed in an X-axis direction and five rows of cells surrounded by the meta atoms 101 are formed in a Y-axis direction. In other words, the meta atoms 101 are disposed in six rows and five columns like dispositions X11, X21, . . . , X15, . . . , X61, X62, . . . , X65 so that longitudinal directions thereof are along the X-axis direction. Further, the meta atoms 101 are disposed in five rows and six columns like dispositions Y11, Y21, . . . , Y51, . . . , Y16, Y26, . . . , Y56 so that longitudinal directions thereof are along the Y-axis direction. Further, in the cell, a width and depth of the lattice are larger than an outer shape of the C-shaped ring member (for example, the ring member 111B) of the meta atom 101.

Further, the through hole 20h is located in the cell located at a center of the meta material 100. Further, when a density of the plasma is controlled, the meta atoms 101C constituting a cell in a peripheral portion and the meta atoms 101D near the cell of the through hole 20h may have different resonance frequencies fr. For example, the meta atom 101C has a resonance frequency fr (=about 2.35 GHZ). Further, for example, the meta atom 101D has a resonance frequency fr (=about 2.25 GHz or about 2.55 GHZ) that is a predetermined frequency (e.g., 0.2 GHZ) away from the resonance frequency fr of the meta atom 101C.

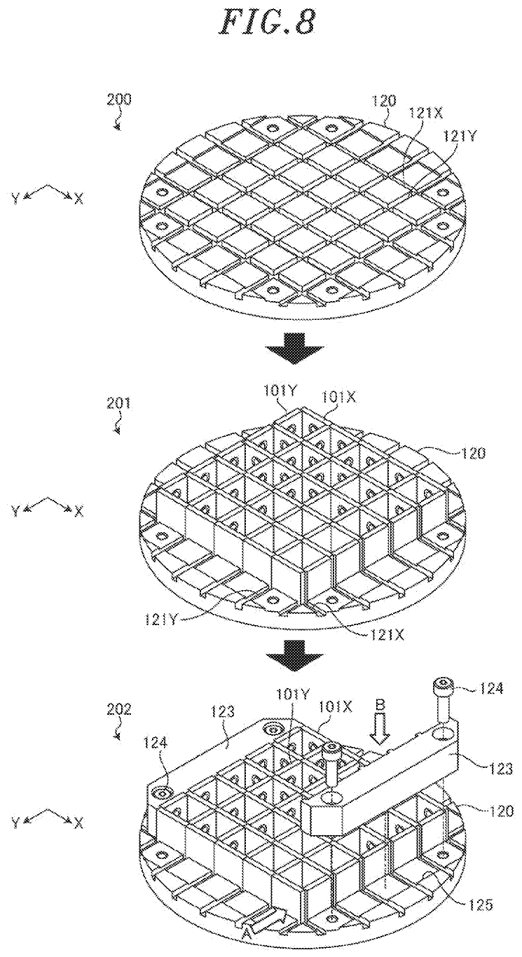

Next, a structure of the meta material 100 will be described according to ab assembly sequence of the meta material 100 using FIGS. 8 to 13. FIG. 8 is a diagram illustrating an example of assembly of the resonator array structure according to the first embodiment. Further, it is assumed that the resonance frequency fr of each meta atom 101 is measured in advance, and a position at which the meta atom 101 is disposed is determined. Further, in description of FIGS. 8 to 13, since the meta material 100 is not attached to the plasma processing apparatus 1, the meta material 100 is assembled in a state in which the meta material 100 is vertically reversed with respect to the meta material 100 attached to the plasma processing apparatus 1. Further, in each of the following drawings, the ring members are drawn in some of the meta atoms 101 to make it easier to understand directions of the meta atoms 101, but in reality, surfaces thereof are covered with a dielectric (insulating film).

A process 200 illustrated in FIG. 8 is a process of preparing the base plate 120. The base plate 120 is made of a dielectric material such as quartz or ceramics, for example. The base plate 120 is provided with a plurality of grooves 121X in an X-axis direction and grooves 121Y in a Y-axis direction as grooves into which the meta atoms 101 are fitted.

A process 201 is a process of fitting each meta atom 101 into the groove 121X or groove 121Y at a corresponding position. In the following description, the meta atom 101 fitted into the groove 121X is referred to as a meta atom 101X, and the meta atom 101 fitted into the groove 121Y is referred to as a meta atom 101Y. Further, it is assumed that the meta atom 101X is wider than the meta atom 101Y, and end portions of the meta atoms 101X are in contact with each other. In process 201, a cell surrounded by the meta atoms 101X and 101Y is formed. Further, the grooves 121X and 121Y have a gap in a thickness direction between the grooves 121X and 121Y and the fitted meta atoms 101X and 101Y to prevent cracking due to thermal expansion. Further, sides of the meta atom 101X and 101Y fitted into the grooves 121X and 121Y are referred to as a first side.

A process 202 is a process of attaching side pressing members 123. In step 202, the two side pressing members 123 are fixed to the base plate 120 using screws 124 so that the two side pressing members 123 come in contact with one side of the meta atoms 101Y in the dispositions Y11 to Y51 and dispositions Y16 to Y56 illustrated in FIG. 2 among the outermost meta atoms 101. Further, the side pressing member 123 and the screw 124 constitute an example of the pressing member, and are formed of ceramics such as alumina which is a dielectric member.

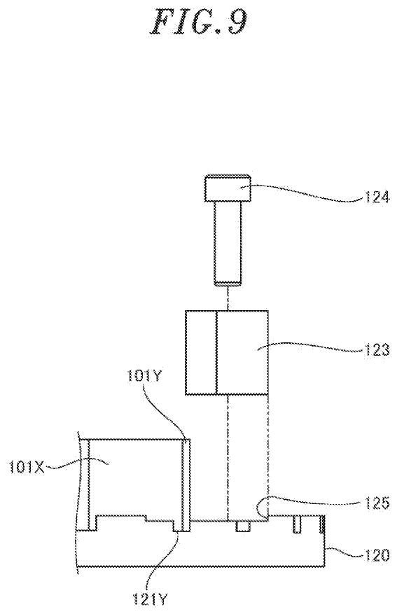

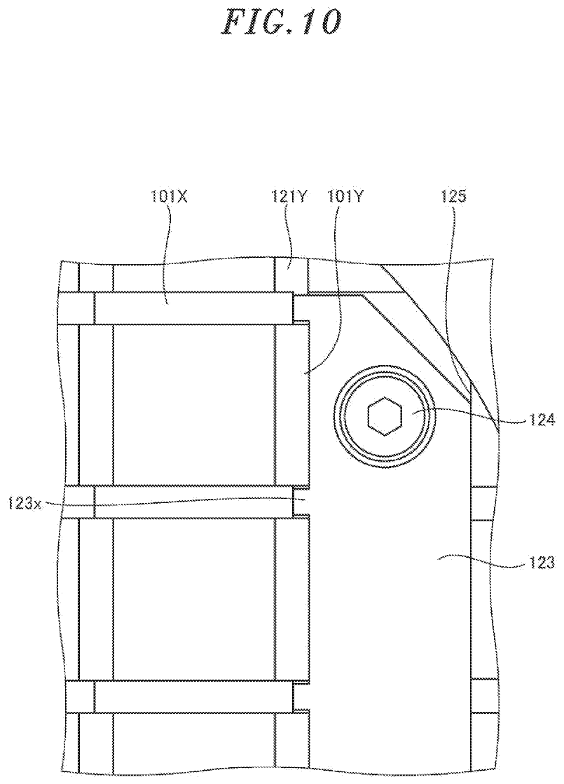

Here, the attachment of the side pressing members 123 as viewed from the sides and upper surfaces in FIG. 8 will be described using FIGS. 9 and 10. FIG. 9 is a side view illustrating an example taken along an arrow A in FIG. 8. FIG. 10 is a top view illustrating an example taken along an arrow B in FIG. 8. As illustrated in FIGS. 9 and 10, the side pressing member 123 is disposed between one side of the outermost meta atom 101Y inserted into the groove 121Y and the step portion 125 provided on the base plate 120, and position adjustment in the X-axis direction is performed by the step portion 125. In this case, position adjustment of an inner surface of the side pressing member 123 is performed so that the inner surface matches an outer surface of the groove 121Y. Further, the side pressing member 123 has a convex portion 123x which is in contact with an end portion of the meta atom 101X at an end portion of the meta atom 101Y. The convex portion 123x fixes the outermost meta atoms 101X and 101Y by coming into contact with end portions of the meta atoms 101X and 101Y. The side pressing member 123 is fixed to the base plate 120 with the screw 124.

FIG. 11 is a diagram illustrating an example of assembly of the resonator array structure according to the first embodiment. A process 203 illustrated in FIG. 11 is a process of attaching side pressing members 127. In the process 203, the two side pressing members 127 are fixed to the base plate 120 using screws 128 so that the two side pressing members 123 come in contact with one side of the meta atoms 101X in the dispositions X11 to X15 and dispositions Y61 to Y65 illustrated in FIG. 2 among the outermost meta atoms 101. Further, the side pressing members 127 and the screws 128 constitute an example of the pressing member, and are formed of ceramics such as alumina which is a dielectric member.

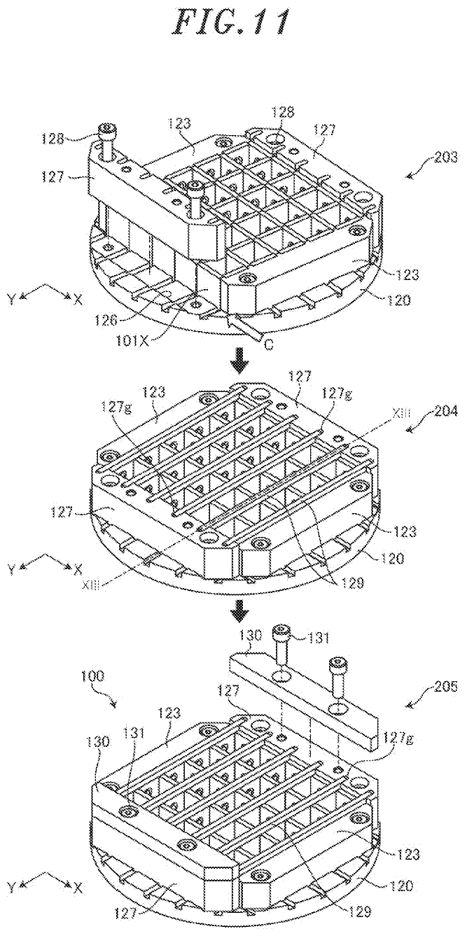

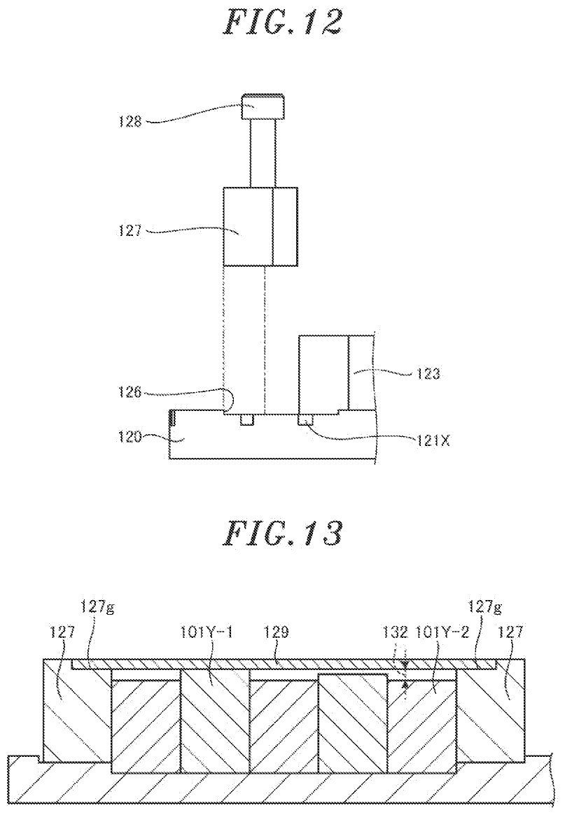

FIG. 12 is a side view illustrating an example taken along an arrow C in FIG. 11. As illustrated in FIG. 12, a side pressing member 127 is disposed between one side of the outermost meta atom 101X fitted into the groove 121X and an end surface of the side pressing member 123, and a step portion 126 provided on the base plate 120. Position adjustment of the side pressing member 127 in the Y-axis direction is performed by the step portion 126. In this case, position adjustment of an inner surface of the side pressing member 127 is performed so that the inner surface matches an outer surface of the groove 121X. Further, since the end portions of the outermost meta atoms 101X are in contact with each other, a concave portion is not formed and there is nothing equivalent to the convex portion 123x of the side pressing member 123.

The description returns to FIG. 11. A process 204 is a process of attaching a pressing member 129 for pressing the meta atoms 101X and 101Y between the two side pressing members 127. In process 204, the pressing member 129 is installed between the two side pressing members 127 to continuously press upper portions (second sides) of the meta atoms 101Y in a longitudinal direction and also press upper end portions of the meta atoms 101X. In other words, the pressing member 129 is installed parallel to the side pressing members 123. In this case, both end portions of the pressing member 129 are fitted into concave portions 127g of the side pressing members 127, respectively. Further, the pressing member 129 is formed of ceramics such as alumina which is a dielectric member.

A process 205 is a process of attaching a member 130 onto the side pressing member 127 in order to fix the pressing member 129. In the process 205, an end portion of the pressing member 129 fitted into the concave portion 127g is fitted between the side pressing member 127 and the member 130, and the member 130 is fixed to the side pressing member 127 by screws 131. Thus, the assembly of the meta material 100 is completed. Further, the member 130 and the screws 131 constitute an example of the pressing member and are formed of ceramics such as alumina which is a dielectric member.

FIG. 13 is a cross-sectional view illustrating an example of a XIII-XIII cross section of FIG. 11. As illustrated in FIG. 13, the respective meta atoms 101Y pressed by the pressing member 129 have a difference in height after disposition due to an error in a height direction between the two side pressing members 127. In FIG. 13, in a first column, an upper portion of the highest meta atom 101Y-1 is in contact with the pressing member 129, but an upper portion of the other meta atom 101Y-2 is not in contact with the pressing member 129. For example, the meta atom 101Y-2 has a gap 132 between the meta atom 101Y-2 and the pressing member 129. However, when the gap 132 is smaller than a depth of the groove 121Y, the meta atom 101Y-2 stays at a disposed place without falling out. That is, in the assembled meta material 100, the meta atoms 101 do not fall out even when the meta material 100 is turned upside down for attachment to the plasma processing apparatus 1.

### [Modification Example 1 of Resonator Array Structure]

Here, Modification Example 1 in which plasma generation at the outermost circumference of the meta material 100 which is a resonator array structure is considered will be described. FIG. 14 is a perspective view illustrating an example of a resonator array structure according to Modification Example 1. A meta material 100a illustrated in FIG. 14 includes side pressing members 123a, screws 124a, side pressing members 127a and screws 128a instead of the side pressing members 123, the screws 124, the side pressing members 127 and the screws 128, unlike the meta material 100. Further, the meta material 100a includes members 130a and screws 131a instead of the member 130 and the screws 131, unlike the meta material 100.

The side pressing member 123a is thinner than the side pressing member 123, thereby forming a space outside the outermost meta atom 101Y. Since the side in contact with the meta atoms 101 of the side pressing member 123a has the same shape as the side pressing member 123, the side pressing member 123a is fixed to the base plate 120 by screws 124a.

The side pressing member 127a forms a space 127b between the side pressing member 127a and the outermost meta atom 101X by a thickness of a portion in contact with the outermost meta atom 101X being made small, unlike the side pressing member 127. Since a lower portion of the side pressing member 127a is in contact with the outermost meta atom 101X, the outermost meta atom 101X can be fixed, like the side pressing member 127. The side pressing member 127a is fixed to the base plate 120 by the screws 128a.

The member 130a is formed by deforming the member 130 according to a shape of the side pressing member 127a. The end portion of the pressing member 129 is fitted between the side pressing member 127a and the member 130a, and the member 130a is fixed to the side pressing member 127a by the screws 131a. Thus, in the meta material 100a, a space can be formed meta outside the outermost atoms 101X and 101Y in consideration of plasma generation. Further, the side pressing member 123a, the screws 124a, the side pressing member 127a, the screws 128a, the member 130a, and the screws 131a constitute an example of the pressing member, and are made of ceramics such as alumina as a dielectric member.

### [Modification Example 2 of Resonator Array Structure]

In the base plate 120 described above, there is a gap between the grooves 121X and 121Y and the fitted meta atoms 101X and 101Y, and the meta atoms 101X and 101Y shake or tilt slightly. Therefore, a case in which the shaking or the like of the meta atoms 101X and 101Y is further curbed will be described as Modification Example 2.

FIG. 15 is a diagram illustrating an example of a range of shaking within the groove of the card-shaped resonator. As illustrated in FIG. 15, for example, when an installation direction of the meta material 100 is a vertical surface, the meta atom 101Y fitted into the groove 121Y of the base plate 120 moves randomly in a left-right direction. Further, since the meta atom 101X is pressed in an up-down direction by the meta atom 101Y, the meta atom 101X does not move to the extent that tilt becomes a problem. An amount of movement of the meta atom 101Y is an amount depending on a depth 140 and a width 141 of the groove 121Y and a length 142 and a width 143 of the meta atom 101Y. For example, a gap 144 between the groove 121Y and the meta atom 101Y on a surface of the base plate 120 is an amount of misalignment 145 on a top of a tip of the meta atom 101Y. Further, at the tip of the meta atom 101Y, a difference 146 occurs between the top of the tip and a bottom of the tip. In this case, there is a tolerance during processing in the width 143 of the meta atom 101Y and the width 141 of the groove 121Y, and when the depth 140 of the groove 121Y is small, the difference 146 is likely to exceed a range that can be handled by the pressing member 129.

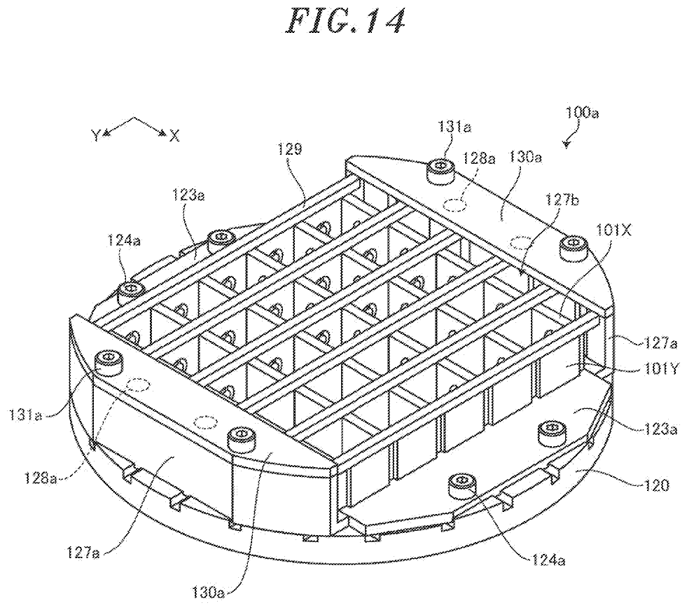

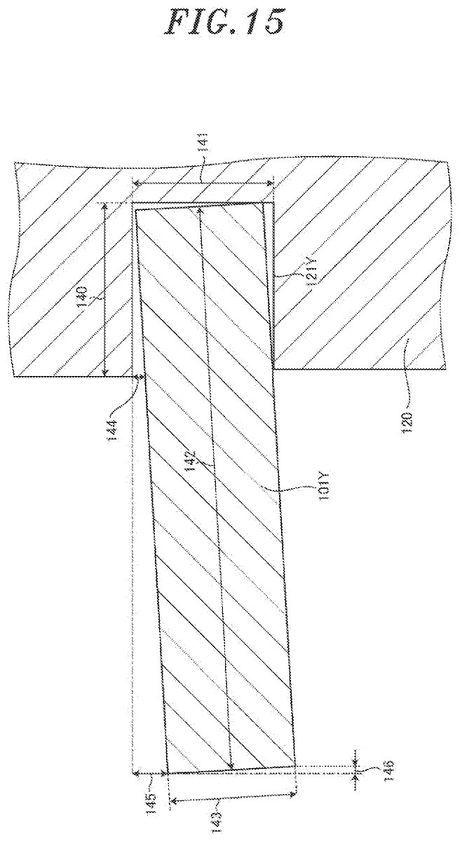

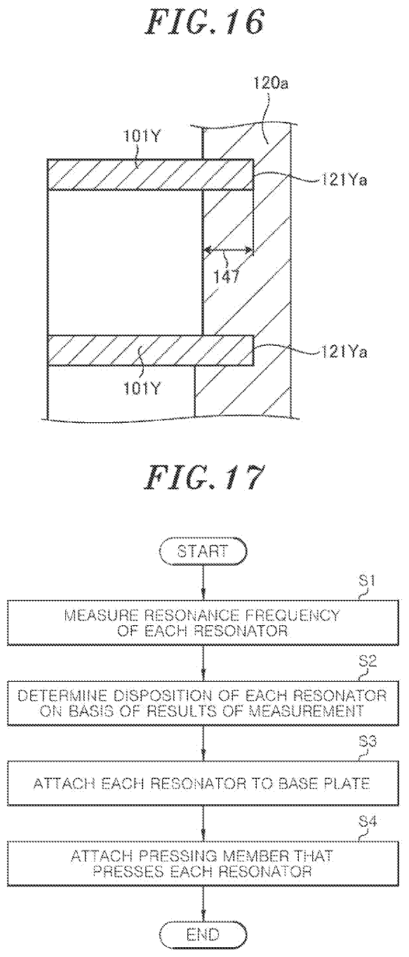

Therefore, when the grooves 121X and 121Y are deepened, the shaking of the meta atoms 101X and 101Y is further curbed. FIG. 16 is a cross-sectional view illustrating examples of the card-shaped resonator and the base plate according to Modification Example 2. A base plate 120a illustrated in FIG. 16 includes a groove 121Ya. Further, the groove 121 in the X direction is omitted. A depth 147 of the groove 121Ya is, for example, twice the depth 140 of the groove 121Y. Accordingly, an amount of misalignment at the top of the tip of the meta atom 101Y in the groove 121Ya becomes half of the amount of misalignment 145.

### [Assembly Method for Resonator Array Structure]

Next, an assembly method for a resonator array structure (meta material) 100 will be described using FIG. 17. FIG. 17 is a flowchart illustrating an example of an assembly method for a resonator array structure according to the first embodiment.

In the first embodiment, first, an operator performing the assembly measures a resonance frequency of each resonator (meta atom) 101 (step S1). The operator determines disposition of the respective resonators, that is, disposition of the grooves 121X and 121Y into which the meta atoms 101 are fitted, on the basis of results of the measurement (step S2). In this case, for example, the operator selects a plurality of meta atoms 101 of which a difference in resonance frequency fr is within a predetermined range, and determines positions of the meta atoms 101 fitted into the grooves 121X and 121Y among the plurality of selected meta atoms 101, and the grooves 121X and 121Y into which the meta atoms 101 are fitted. That is, the operator determines the meta atoms 101X and 101Y corresponding to the dispositions X11, . . . , X65 and the dispositions Y11, . . . , Y56 in the example of FIG. 2.

The operator fits the respective resonators (meta atoms) 101 into the grooves 121X and 121Y and attaches the respective resonators (meta atoms) 101 to the base plate 120, on the basis of the determined array of the resonators (meta atoms) 101 (step S3). The operator attaches the pressing member 129 that presses the respective resonators (meta atoms) 101 (step S4). Thus, the assembly of the resonator array structure (meta material) 100 can be completed.

### [Modification Examples 3 to 10 of Resonator Array Structure]

Next, modification of an array of the meta atoms 101 will be described as Modification Examples 3 to 10 of the resonator array structure (meta material) 100. Further, in Modification Examples 3 to 10, a portion of the meta atom 101 under the pressing member is shaded for ease of understanding. Further, pressing members and pressing screws in Modification Examples 3 to 10 constitute an example of the pressing member and are formed of a dielectric (insulator) such as alumina, like the pressing member 129 in the first embodiment.

FIG. 18 is a diagram illustrating an example of an array of card-shaped resonators according to Modification Example 3. In Modification Example 3 illustrated in FIG. 18, meta atoms 101 having the same shape, such as meta atoms 101B, are used as the meta atoms 101 to be used. In the meta atoms 101B disposed in a lattice shape, upper surfaces of end portions of the meta atoms 101B disposed in an X-axis direction and upper surfaces of the meta atoms 101B disposed in a Y-axis direction are pressed by a pressing member 150.

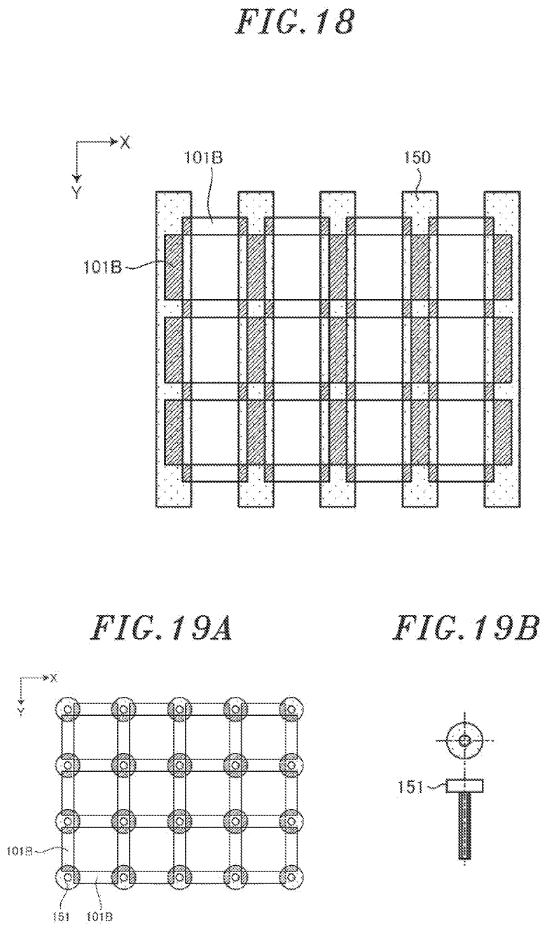

FIGS. 19A and 19B are diagrams illustrating an example of an array of card-shaped resonators according to Modification Example 4. In Modification Example 4 illustrated in FIGS. 19A and 19B, meta atoms 101 having the same shape, such as meta atoms 101B, are used as the meta atoms 101. Further, as illustrated in FIG. 19A, in the meta atoms 101B disposed in a lattice shape, upper surfaces of end portions of the respective meta atoms 101B are pressed by pressing screws 151 illustrated in FIG. 19B.

FIG. 20 is a diagram illustrating an example of an array of card-shaped resonators according to Modification Example 5. In Modification Example 5 illustrated in FIG. 20, meta atoms 101 having the same shape, such as meta atoms 101B, are used as the meta atoms 101. Further, in Modification Example 5, a shape of a cell surrounded by the respective meta atoms 101B is a shape of a regular triangle. In the meta atoms 101B disposed in the shape of the regular triangle, upper surfaces of the meta atoms 101B disposed in a Y-axis direction and upper surfaces of end portions of the meta atoms 101B disposed in an inclined direction are pressed by pressing members 152.

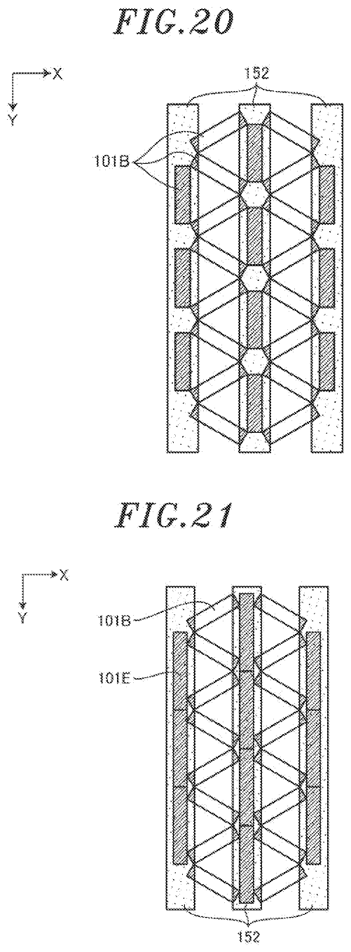

FIG. 21 is a diagram illustrating an example of an array of card-shaped resonators according to Modification Example 6. In Modification Example 6 illustrated in FIG. 21, meta atoms 101 having two types of length, such as meta atoms 101B and meta atoms 101E longer than the meta atom 101B are used as meta atoms 101 to be used. Further, in Modification Example 6, a shape of a cell surrounded by the meta atoms 101B and the meta atoms 101E is a shape of a regular triangle. Further, the meta atoms 101E are disposed so that end portions thereof are in contact with each other. In the meta atoms 101B and 101E disposed in the shape of the regular triangle, upper surface of the meta atoms 101E disposed in a Y-axis direction and upper surfaces of end portions of the meta atoms 101B disposed in an inclined direction are pressed by pressing members 152.

FIG. 22 is a diagram illustrating an example of an array of card-shaped resonators according to Modification Example 7. In Modification Example 7 illustrated in FIG. 22, meta atoms 101 having two types of length, such as meta atoms 101B and meta atoms 101F longer than the meta atom 101B, are used as meta atoms 101 to be used. Further, in Modification Example 7, a shape of a cell surrounded by the meta atoms 101B and the meta atoms 101F is a shape of a regular triangle. Further, among the meta atoms 101F, the meta atoms 101F disposed in the same direction are disposed so that end portions thereof are in contact with each other. In the meta atoms 101B and the meta atoms 101F disposed in the shape of the regular triangle, upper surface of the meta atoms 101B disposed in a Y-axis direction and upper surfaces of end portions of the meta atoms 101F disposed in an inclined direction are pressed by pressing members 153. In this case, the pressing members 153 may be disposed so that the pressing members 153 do not protrude into a space of the cell.

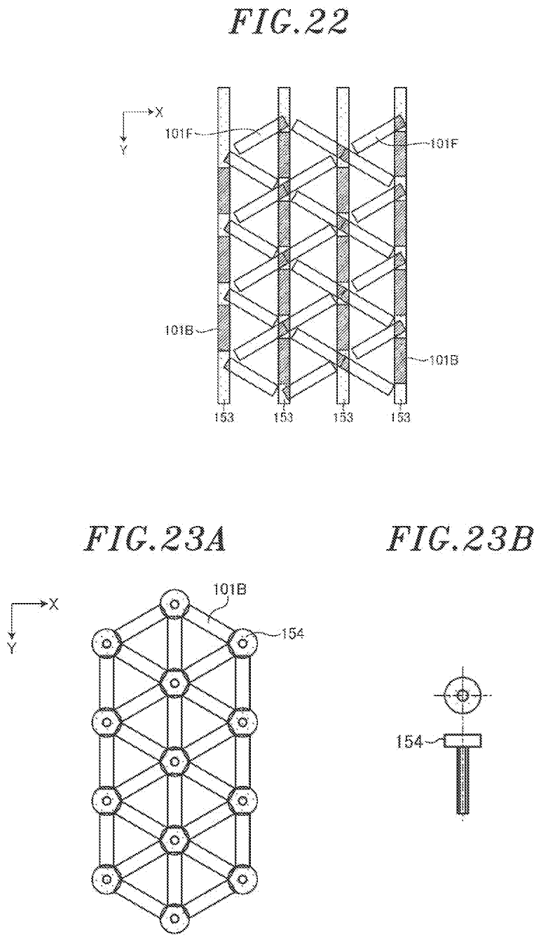

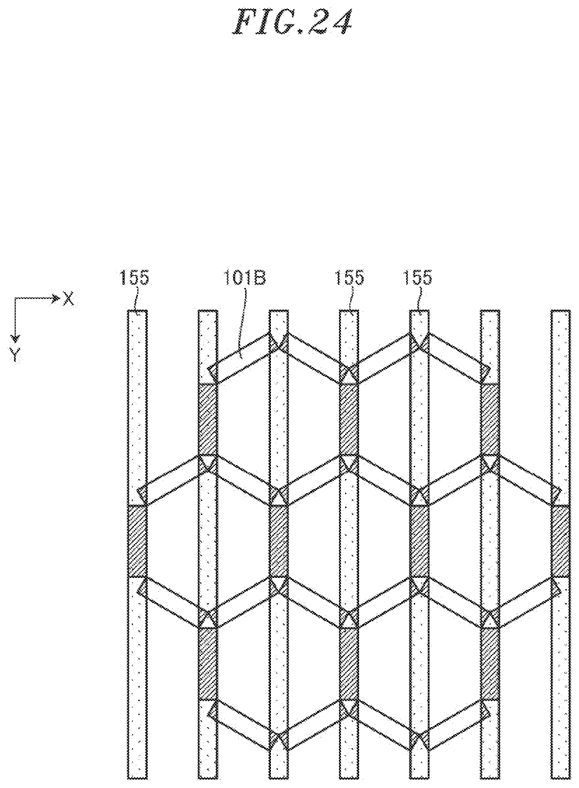

FIGS. 23A and 23B are diagrams illustrating an example of an array of card-shaped resonators according to Modification Example 8. In Modification Example 8 illustrated in FIGS. 23A and 23B, meta atoms 101 having the same shape, such as meta atoms 101B, are used as meta atoms 101 to be used. Further, in Modification Example 8, as illustrated in FIG. 23A, a shape of the cell surrounded by the respective meta atoms 101B is a shape of a regular triangle. In the meta atoms 101B disposed in the shape of the regular triangle, upper surfaces of end portions of the respective meta atom 101B are pressed by pressing screws 154 illustrated in FIG. 23B.

FIG. 24 is a diagram illustrating an example of an array of card-shaped resonators according to Modification Example 9. In Modification Example 9 illustrated in FIG. 24, meta atoms 101 having the same shape, such as meta atoms 101B, are used as the meta atoms 101 to be used. Further, in Modification Example 9, a shape of a cell surrounded by the meta atoms 101B is a shape of a regular hexagon. In the meta atoms 101B disposed in the shape of the regular hexagon, upper surfaces of the meta atoms 101B disposed in a Y-axis direction and upper surfaces of end portions of the meta atoms 101B disposed in an inclined direction are pressed by pressing members 155. In this case, the pressing members 155 may be disposed so that the pressing members 155 do not protrude into a space of the cell.

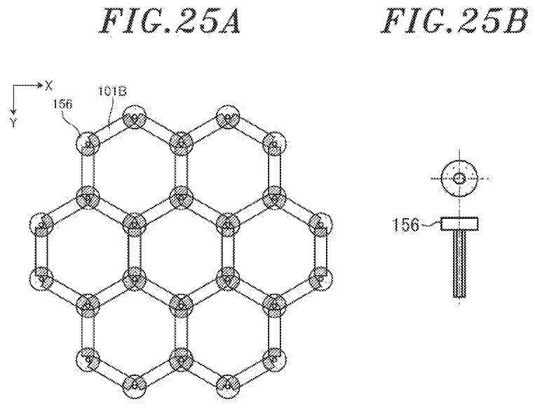

FIGS. 25A and 25B are diagrams illustrating an example of an array of card-shaped resonators according to Modification Example 10. In Modification Example 10 illustrated in FIGS. 25A and 25B, meta atoms 101 having the same shape, such as meta atoms 101B, are used as meta atoms 101 to be used. Further, in Modification Example 10, as illustrated in FIG. 25A, a shape of a cell surrounded by the meta atoms 101B is a shape of a regular hexagon. In the meta atoms 101B disposed in the shape of the regular hexagon, upper surfaces of end portions of the respective meta atoms 101B are pressed by pressing screws 156 illustrated in FIG. 25B.

### Second Embodiment

Although the meta material 100 has been constructed using the card-shaped meta atom 101 in the first embodiment, the meta material may be constructed using a rectangular-shaped resonator (meta atom), and an embodiment in this case will be described as a second embodiment. Further, since a plasma processing apparatus in the second embodiment is the same as the first embodiment described above except for a configuration of the meta material, description of the repeated configuration and operation will be omitted.

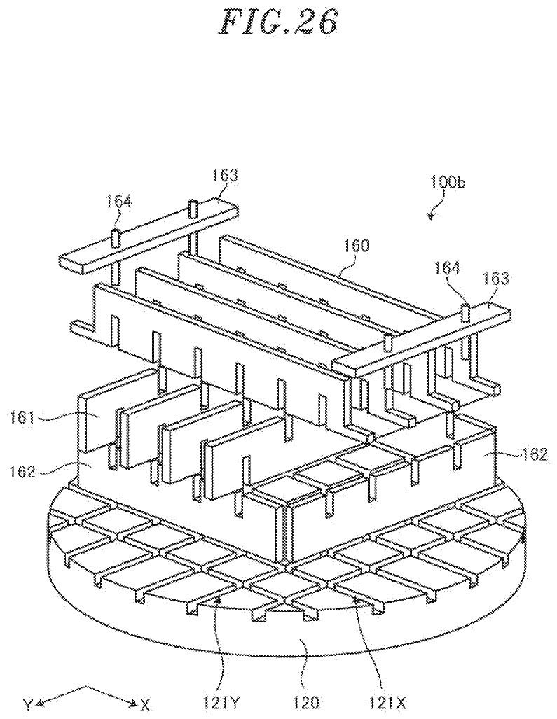

FIG. 26 is a diagram illustrating an example of assembly of the resonator array structure according to the second embodiment. In a meta material (resonator array structure) 100b illustrated in FIG. 26, rectangular-shaped resonators 160 to 162 are assembled so that a lattice-shaped cell is formed. Further, in the following description, the rectangular resonators 160 to 162 may be referred to as meta atoms 160 to 162. In the example of FIG. 26, the meta atoms 160 to 162 are assembled so that, the cells formed of the meta atoms 160 to 162, are formed five columns in an X-axis direction and five rows in a Y-axis direction, as in the first embodiment. Further, in measurement of a resonance frequency fr of the meta atoms 160 to 162, the resonance frequency fr may be measured using a vector network analyzer in which transmitting and receiving antennas are disposed with longitudinal directions of the meta atoms 160 to 162 interposed therebetween.

In the assembly of the meta material 100b, first, four meta atoms 162 on the outermost circumference are fitted into grooves 121X and 121Y to form a square. Next, respective meta atoms 161 are inserted into the groove 121Y in the Y-axis direction surrounded by the meta atoms 162. Next, the respective meta atoms 160 are fitted into the grooves 121X in the X-axis direction surrounded by the meta atoms 162. Finally, both end portions of the meta atoms 160 are fixed to a base plate 120 by pressing members 163 and screws 164. Further, the pressing members 163 and the screws 164 constitute an example of a pressing member, and are formed of ceramics such as alumina which is a dielectric member.

FIGS. 27 to 29 are diagrams illustrating an example of a configuration of the rectangular resonator according to the second embodiment. Further, in FIGS. 27 to 29, ring members are drawn in the meta atoms 160 to 162 so that disposition of the ring members within the meta atoms 160 to 162 is easily understand, but in reality, surfaces thereof are covered with a dielectric (insulating film). As illustrated in FIG. 27, the meta atom 160 has a laterally elongated rectangular shape in which five card-shaped meta atoms 101 of the first embodiment are connected laterally. In other words, the meta atom 160 has five structures in which a dielectric plate 160b is disposed between two C-shaped ring members 160a made of a conductor, which are ring members 160a (a set of ring members 160a) disposed adjacent to each other in opposite directions. Further, the meta atom 160 includes a groove 160c and an end portion 160d. Six grooves 160c are formed on the lower side of the meta atom 160, the four inner grooves are engaged with the grooves 161c of the meta atom 161, which will be described later, and the two outer grooves are engaged with the groove 162c of the meta atom 162. The end portion 160d is pressed by the pressing member 163, and the pressing member 163 is fixed to the base plate 120 by the screws 164, so that the meta atom 160 is fixed to the base plate 120.

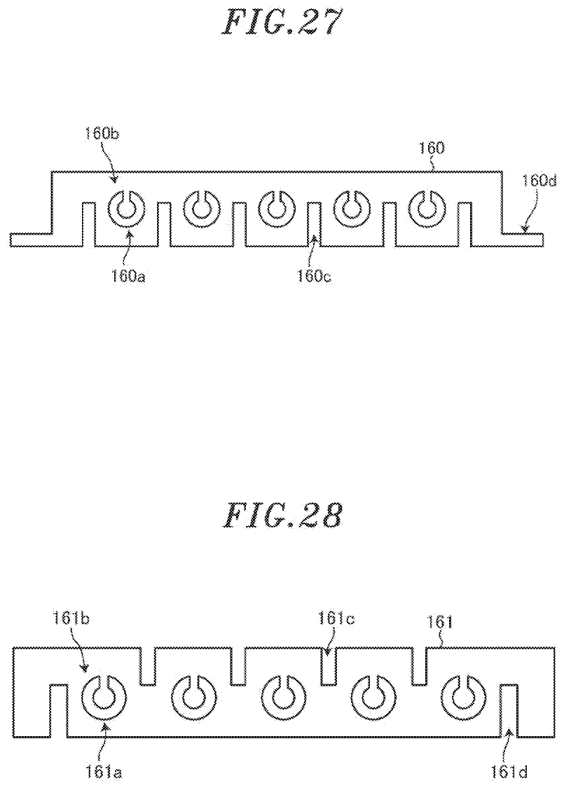

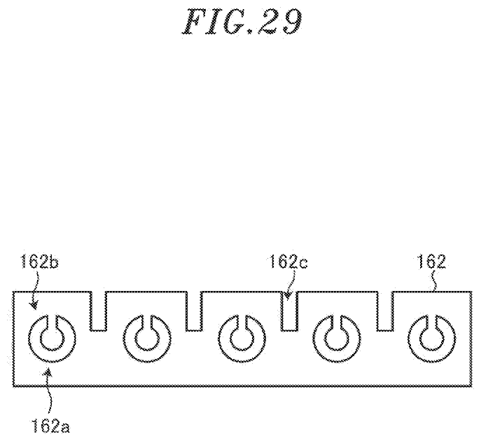

As illustrated in FIG. 28, the meta atom 161 has a laterally elongated rectangular shape in which five card-shaped meta atoms 101 of the first embodiment are connected laterally. In other words, the meta atom 161 has five structures in which a dielectric plate 161b is disposed between two C-shaped ring members 161a made of a conductor, which are ring members 161a (a set of ring members 161a) disposed adjacent to each other in opposite directions. Further, the meta atom 161 includes grooves 161c and grooves 161d. Four grooves 161c are formed on the upper side of the meta atom 161 and engaged with the respective grooves 160c of the meta atom 160. Two grooves 161d are formed on the lower side of the meta atom 161 and engaged with the grooves 162c of the meta atom 162, which will be described later.

As illustrated in FIG. 29, the meta atom 162 has a horizontally elongated rectangular shape in which five card-shaped meta atoms 101 in the first embodiment are connected laterally. In other words, the meta atom 162 has five structures in which a dielectric plate 162b is disposed between two C-shaped ring members 162a made of a conductor, which are ring members 162a (a set of ring members 162a) disposed adjacent to each other in opposite directions. Further, the meta atom 162 includes grooves 162c. Four grooves 162c are formed on the upper side of the meta atom 162 and engaged with the grooves 161d of the meta atom 161. Thus, even when the meta atoms 160 to 162 which are rectangular resonators are used, a lattice-shaped cell can be formed, and a resonator array structure can be formed as the meta material 100b. Further, in the meta atoms 160 to 162, the resonance frequency fr may be changed for each set of ring members 160a to 162a within the same meta atom 160 to 162. Further, some of the ring members 160a to 162a may not be provided. Further, the meta atoms 160 to 162 may be assembled so that the cell has a shape of a regular triangle.

### OTHER MODIFICATION EXAMPLES

In each of the above embodiments, a case in which the meta materials 100, 100a, and 100b are disposed along the lower surface 20a of the dielectric window 20 has been described as an example, but the present disclosure is not limited thereto. For example, the meta materials 100, 100a, and 100b may be disposed to be spaced apart from the lower surface 20a of the dielectric window 20. Further, the meta materials 100, 100a, and 100b may be disposed along the upper surface of the electrostatic chuck 14c provided with the upper surface facing the processing space S, or may be disposed to be spaced apart from the upper surface of the electrostatic chuck 14c. Further, the meta materials 100, 100a, and 100b may be disposed along the inner wall surface of the side wall 12a of the processing container 12, or may be disposed to be spaced apart from the inner wall surface of the side wall 12a of the processing container 12. In short, the meta materials 100, 100a, and 100b may be disposed along the first surface of the member provided with one side (the first surface) facing the processing space S, or may be disposed to be spaced apart from the first surface of the member.

Further, in each of the embodiments, the output portion of the microwave output apparatus 16 may be connected to the base 14a, which is the high frequency electrode. In this case, the base 14a supplies the microwaves output from the microwave output apparatus 16 to the processing space S via the electrostatic chuck 14c. Further, in this configuration, the meta materials 100, 100a, and 100b may be embedded in the electrostatic chuck 14c.

Further, in the first embodiment, a case in which the meta materials 100 and 100a are formed by arranging the plurality of meta atoms 101 that are capable of resonating with the magnetic field component of the microwaves and have a size smaller than the wavelength of microwaves in a lattice shape, a triangular shape, or a hexagonal shape has been described by way of example. The present disclosure is not limited thereto, and an array of the plurality of meta atoms 101 may be any array. For example, the plurality of meta atoms 101 may be arranged at predetermined intervals along one direction.

Further, in each of the embodiments, a case in which the microwaves output from the microwave output apparatus 16 are propagated to the dielectric window 20 via the waveguide 21, the mode converter 27, the coaxial waveguide 28, and the antenna 18 has been described by way example. The present disclosure is not limited thereto, and the microwaves may be propagated directly to the dielectric window 20 through the waveguide 21 without passing through the mode converter 27 and the coaxial waveguide 28. Accordingly, the waveguide 21 functions as an electromagnetic wave supply portion that supplies microwaves to the processing space S through the dielectric window 20. In this case, the mode converter 27, the coaxial waveguide 28, the slot plate 30, and the dielectric plate 32 may be omitted. Thus, the microwaves are directly propagated to the dielectric window 20 through the waveguide 21, thereby generating the plasma directly under the meta materials 100, 100a, and 100b without generating the plasma directly under the dielectric window 20.

As described above, according to each embodiment, the plasma processing apparatus 1 includes the processing container 12, the electromagnetic wave generator (microwave output apparatus 16), the dielectric (dielectric window 20), and the electromagnetic wave supply portion (antenna 18), and the resonator array structure (meta material 100, 100a, or 100b). The processing container 12 provides the processing space S. The electromagnetic wave generator generates electromagnetic waves for plasma excitation to be supplied to the processing space S. The dielectric is provided with the first surface facing the processing space S. The electromagnetic wave supply portion supplies the electromagnetic waves to the processing space S through the dielectric. The resonator array structure is located along the first side of the dielectric within the processing container 12. Further, the resonator array structure includes the base plate 120, the plurality of resonators (meta atoms 101, and 160 to 162), and the pressing members (side pressing members 123 and 127 and the pressing members 129 and 163). The base plate 120 includes the grooves (grooves 121X and 121Y) on the surface on the processing space S side. The plurality of resonators are capable of resonating with the magnetic field component of the electromagnetic wave and have a size smaller than the wavelength of the electromagnetic wave. The pressing member presses the plurality of resonators. Further, the plurality of resonators have a structure in which C-shaped ring members (ring members 111B, 160a, 161a, and 162a) made of a conductor are stacked on one side of the dielectric plate (dielectric plates 112B, 160b, 161b, and 162b), and the first sides thereof are fitted into the grooves. Further, the pressing member presses the plurality of resonators toward the base plate 120. As a result, it is possible to realize high density in a wide range of plasma.

Further, according to each embodiment, the plurality of resonators have a structure in which two C-shaped ring members oriented in opposite directions and having a concentric shape are stacked on one side of the dielectric plate. As a result, it is possible to cause the electromagnetic waves to resonate with the plurality of resonators using a plurality of resonators having a simple structure.

Further, according to the first embodiment, each of the plurality of resonators is formed in a card shape for each set of two C-shaped ring members, and the plurality of card-shaped resonators are fitted into the grooves in a vertical direction. As a result, it is possible to easily perform replacement of the resonators.

Further, according to the second embodiment, each of the plurality of resonators includes sets of two C-shaped ring members and is formed in a rectangular shape in which a plurality of sets are connected, and the plurality of resonators having the rectangular shape are fitted into the groove in a vertical direction. As a result, it is possible to easily perform replacement of the resonators in units of the plurality of resonators having the rectangular shape.

Further, according to each embodiment, the grooves are provided in a lattice shape. As a result, a square cell can be formed.

Further, according to each embodiment, the groove is provided in the shape of the regular triangle. As a result, the cell having a shape of a regular triangle can be formed and rigidity can be improved.

Further, according to the first embodiment, the groove is provided in a regular hexagon shape. As a result, the regular hexagonal cell can be formed and rigidity can be improved.

Further, according to the first embodiment, the pressing member presses the second sides opposite to the first sides of the plurality of resonators and is fixed to the base plate. As a result, it is possible to prevent the plurality of resonators from falling out.

Further, according to each embodiment, the grooves are provided to form the cell surrounded by the plurality of resonators fitted in the grooves. As a result, it is possible to easily set a shape of the cell.

Further, according to each embodiment, the cell has a width and depth larger than an outer shape of the C-shaped ring member. As a result, it is possible to divide plasma into each cell space.

Further, according to each embodiment, the plurality of resonators are formed to have a thickness smaller than a width of the groove. As a result, it is possible to prevent the resonator from cracking due to thermal expansion.

Further, according to the first embodiment, the resonance frequencies of the plurality of resonators are measured for each card shape, and the grooves into which the resonators are fitted are determined based on results of the measurement. As a result, it is possible to form a resonator array structure of which a resonance frequency is within a predetermined range.

Further, according to the second embodiment, the resonance frequencies of the plurality of resonators are measured for each rectangular shape, and the grooves into which the resonators are fitted are determined based on results of the measurement. As a result, it is possible to form a resonator array structure of which a resonance frequency is within a predetermined range.

Further, according to each embodiment, the C-shaped ring member is further covered with a dielectric. As a result, it is possible to curb abnormal discharge in each of the plurality of resonators. Further, it is possible to improve heat resistance and plasma resistance.

Further, according to each embodiment, in the assembly method for a resonator array structure in the plasma processing apparatus 1, the plasma processing apparatus 1 includes the processing container 12, the electromagnetic wave generator (microwave output apparatus 16), the dielectric (dielectric window 20), and the electromagnetic wave supply portion (antenna 18), and the resonator array structure (meta material 100, 100a, or 100b). The processing container 12 provides the processing space S. The electromagnetic wave generator generates electromagnetic waves for plasma excitation to be supplied to the processing space S. The dielectric is provided with the first surface facing the processing space S. The electromagnetic wave supply portion supplies the electromagnetic waves to the processing space S through the dielectric. The resonator array structure is located along the first side of the dielectric within the processing container 12. Further, the resonator array structure includes the base plate 120, the plurality of resonators (meta atoms 101, and 160 to 162), and the pressing members (side pressing members 123 and 127 and the pressing members 129 and 163). The base plate 120 includes the grooves (grooves 121X and 121Y) on the surface on the processing space S side. The plurality of resonators are capable of resonating with the magnetic field component of the electromagnetic wave and have a size smaller than the wavelength of the electromagnetic wave. The pressing member presses the plurality of resonators. The assembly method for a resonator array structure includes measuring a resonance frequency of each of the plurality of resonators, determining a disposition of the grooves into which the respective resonators are fitted on the basis of results of the measurement, fitting each corresponding resonator into each determined disposition of the groove, and pressing the plurality of fitted resonators toward the base plate using the pressing member. As a result, it is possible to realize high density in a wide range of plasma, and to easily perform replacement of the resonators.

Each of the embodiments disclosed this time should be considered as being illustrative in all respects and not restrictive. Each of the above-described embodiments may be omitted, replaced, or changed in various forms without departing from the scope of the appended claims and the spirit thereof.

Further, the present disclosure can also have the following configurations.

(1)

A plasma processing apparatus comprising:
a processing container configured to provide a processing space;
an electromagnetic wave generator configured to generate electromagnetic waves for plasma excitation supplied to the processing space;
a dielectric provided with a first surface thereof facing the processing space;
an electromagnetic wave supply portion configured to supply the electromagnetic waves to the processing space through the dielectric; and
a resonator array structure located along the first surface of the dielectric within the processing container,
wherein the resonator array structure includes:
a base plate having a groove on a surface on the processing space side;
a plurality of resonators capable of resonating with a magnetic field component of the electromagnetic wave and having a size smaller than a wavelength of the electromagnetic wave; and
a pressing member configured to press the plurality of resonators,
wherein the plurality of resonators includes:
a dielectric plate; and
a conductor member being stacked on one side of the dielectric plate,
wherein a first side of each of the plurality of resonators are fitted into the groove, and
wherein the pressing member presses the plurality of resonators toward the base plate.
   (2)

The plasma processing apparatus of (1), wherein the conductor member has two C-shaped ring members oriented in opposite directions and having a concentric shape.

(3)

The plasma processing apparatus of (2), wherein each of the plurality of resonators is formed in a card shape and has one conductor member, and the each of the plurality of card-shaped resonators are fitted into the groove in a vertical direction.

(4)

The plasma processing apparatus of (2), wherein each of the plurality of resonators is formed in a rectangular shape and has a plurality of conductor members, and the each of the plurality of resonators having the rectangular shape are fitted into the groove in a vertical direction.

(5)

The plasma processing apparatus of (3) or (4), wherein the groove is provided in a lattice shape.

(6)

The plasma processing apparatus of (3) or (4), wherein the groove is provided in a regular triangle shape.

(7)

The plasma processing apparatus of (3), wherein the groove is provided in a regular hexagon shape.

(8)

The plasma processing apparatus of (3), wherein the pressing member presses a second side of the each of the plurality of resonators facing the first sides and is fixed to the base plate.

(9)

The plasma processing apparatus of any one of (3) to (8), wherein the groove is provided to be able to form a cell surrounded by the plurality of resonators fitted into the groove.

(10)

The plasma processing apparatus of (9), wherein the cell has a width and depth larger than an outer shape of the conductor member.

(11)

The plasma processing apparatus of any one of (3) to (10), wherein the plurality of resonators are formed to have a thickness thinner than a width of the groove.

(12)

The plasma processing apparatus of (3), wherein resonance frequencies of each of the plurality of card-shape resonators are measured, and a disposition of the groove into which the each of the plurality of card-shape resonators is fitted are determined based on results of the measurement.

(13)

The plasma processing apparatus of (4), wherein resonance frequencies of each of the plurality of rectangular shape resonators are measured, and a disposition of the groove into which the each of the plurality of the rectangular shape resonators are fitted are determined based on results of the measurement.

(14)

The plasma processing apparatus of any one of (1) to (13), wherein the C-shaped ring member is further covered by a dielectric.

(15)

An assembly method for a resonator array structure in a plasma processing apparatus,
wherein the plasma processing apparatus includes:
a processing container configured to provide a processing space;
an electromagnetic wave generator configured to generate electromagnetic waves for plasma excitation supplied to the processing space;
a dielectric provided with a first surface thereof facing the processing space;
an electromagnetic wave supply portion configured to supply the electromagnetic waves to the processing space through the dielectric; and
a resonator array structure located along the first surface of the dielectric within the processing container,
the resonator array structure includes:
a base plate having a groove on a surface on the processing space side;
a plurality of resonators capable of resonating with a magnetic field component of the electromagnetic wave and having a size smaller than a wavelength of the electromagnetic wave; and
a pressing member configured to press the plurality of resonators, and
the assembly method comprises:
measuring a resonance frequency of each of the plurality of resonators;
determining a disposition of the groove into which each of the respective resonator is fitted on the basis of results of the measurement;
fitting each corresponding resonator into each determined disposition of the groove; and
pressing the plurality of fitted resonators toward the base plate using the pressing member.

1. A plasma processing apparatus comprising:
a processing container configured to provide a processing space;
an electromagnetic wave generator configured to generate electromagnetic waves for plasma excitation supplied to the processing space;
a dielectric provided with a first surface thereof facing the processing space;
an electromagnetic wave supply portion configured to supply the electromagnetic waves to the processing space through the dielectric; and
a resonator array structure located along the first surface of the dielectric within the processing container,
wherein the resonator array structure includes:
a base plate having a groove on a surface on the processing space side;
a plurality of resonators capable of resonating with a magnetic field component of the electromagnetic wave and having a size smaller than a wavelength of the electromagnetic wave; and
a pressing member configured to press the plurality of resonators,
wherein the plurality of resonators includes:
a dielectric plate; and
a conductor member being stacked on one side of the dielectric plate,
wherein a first side of each of the plurality of resonators are fitted into the groove, and
wherein the pressing member presses the plurality of resonators toward the base plate.

2. The plasma processing apparatus of claim 1, wherein the conductor member has two C-shaped ring members oriented in opposite directions and having a concentric shape.

3. The plasma processing apparatus of claim 2, wherein each of the plurality of resonators is formed in a card shape and has one conductor member, and the each of the plurality of card-shaped resonators are fitted into the groove in a vertical direction.

4. The plasma processing apparatus of claim 2, wherein each of the plurality of resonators is formed in a rectangular shape and has a plurality of conductor members, and the each of the plurality of resonators having the rectangular shape are fitted into the groove in a vertical direction.

5. The plasma processing apparatus of claim 3, wherein the groove is provided in a lattice shape.

6. The plasma processing apparatus of claim 3, wherein the groove is provided in a regular triangle shape.

7. The plasma processing apparatus of claim 3, wherein the groove is provided in a regular hexagon shape.

8. The plasma processing apparatus of claim 3, wherein the pressing member presses a second side of the each of the plurality of resonators facing the first sides and is fixed to the base plate.

9. The plasma processing apparatus of claim 3, wherein the groove is provided to be able to form a cell surrounded by the plurality of resonators fitted into the groove.

10. The plasma processing apparatus of claim 4, wherein the groove is provided to be able to form a cell surrounded by the plurality of resonators fitted into the groove.

11. The plasma processing apparatus of claim 9, wherein the cell has a width and depth larger than an outer shape of the conductor member.

12. The plasma processing apparatus of claim 10, wherein the cell has a width and depth larger than an outer shape of the conductor member.

13. The plasma processing apparatus of claim 3, wherein the plurality of resonators are formed to have a thickness thinner than a width of the groove.

14. The plasma processing apparatus of claim 4, wherein the plurality of resonators are formed to have a thickness thinner than a width of the groove.

15. The plasma processing apparatus of claim 3, wherein resonance frequencies of each of the plurality of card-shape resonators are measured, and a disposition of the groove into which the each of the plurality of card-shape resonators is fitted are determined based on results of the measurement.

16. The plasma processing apparatus of claim 4, wherein resonance frequencies of each of the plurality of rectangular shape resonators are measured, and a disposition of the groove into which the each of the plurality of the rectangular shape resonators are fitted are determined based on results of the measurement.

17. The plasma processing apparatus of claim 2, wherein the C-shaped ring member is further covered by a dielectric.

18. An assembly method for a resonator array structure in a plasma processing apparatus,
wherein the plasma processing apparatus includes:
a processing container configured to provide a processing space;
an electromagnetic wave generator configured to generate electromagnetic waves for plasma excitation supplied to the processing space;
a dielectric provided with a first surface thereof facing the processing space;
an electromagnetic wave supply portion configured to supply the electromagnetic waves to the processing space through the dielectric; and
a resonator array structure located along the first surface of the dielectric within the processing container,
the resonator array structure includes:
a base plate having a groove on a surface on the processing space side;
a plurality of resonators capable of resonating with a magnetic field component of the electromagnetic wave and having a size smaller than a wavelength of the electromagnetic wave; and
a pressing member configured to press the plurality of resonators, and
the assembly method comprises:
measuring a resonance frequency of each of the plurality of resonators;
determining a disposition of the groove into which each of the respective resonator is fitted on the basis of results of the measurement;
fitting each corresponding resonator into each determined disposition of the groove; and
pressing the plurality of fitted resonators toward the base plate using the pressing member.
